(19) United States
(12) Patent Application Publication
(10) Pub. No.: US 2006/0096855 A1
(43) Pub. Date: May 11, 2006

(54) Cathode arrangement for atomizing a rotatable target pipe

(76) Inventors: Richard Newcomb, Johnstown, CO (US); Scott Trube, Loveland, CO (US); Tom Riso, Elizabeth, CO (US); Ken Kawakami, Fort Collins, CO (US); Dietmar Marquardt, Erlensee (DE); Andreas Sauer, GroBostheim (DE)

Correspondence Address: COOLEY GODWARD LLP;ATTN: PATENT GROUP, 11951 FREEDOM DRIVE, SUITE 1700, ONE FREEDOM SQUARE- RESTON TOWN CENTER, RESTON, VA, 20190-5061, US

(21) Appl. No.: 10/983,179

(22) Filed: Nov. 5, 2004

(51) Int. Cl. C23C 14/00

(52) U.S. Cl. 204/298.02; 204/298.15

(57) ABSTRACT

A quick attachment system for cathodes is described. One embodiment of the system comprises a laterally movable support shaft; a flange connected to the support shaft, the flange including a cavity locking element and a shoulder locking element; a bordering separator connectable to a target pipe, the bordering separator comprising ring extensions for engaging the cavity locking element of flange; and a straining ring configured to engage the bordering separator and the shoulder locking element of the flange to thereby secure the laterally movable shaft to the target pipe.

### COPYRIGHT

A portion of the disclosure of this patent document contains material that is subject to copyright protection. The copyright owner has no objection to the facsimile reproduction by anyone of the patent disclosure, as it appears in the Patent and Trademark Office patent files or records, but otherwise reserves all copyright rights whatsoever.

### FIELD OF THE INVENTION

The present invention relates to a cathode arrangement. In particular, embodiments of the present invention relate to cathode attachment systems.

### BACKGROUND

In the vacuum coating technique, rotating coating cathodes are being used more frequently. This usually involves a pipe rotatable around the longitudinal axis, having a magnetic system fixed in the interior. An advantage of this rotation cathode compared with planar cathodes is a much better utilization of the target material, and consequently, greater serviceable life.

This tubular cathode is essentially distinguished by two principles of configuration. The explanation of the two principles follows in the examples of horizontal coating equipment.

In the first principle, the complete drive unit, including the media supply on the cover of the coating chamber in the form of so-called end blocks or end heads is mounted on each of the pipe ends. For target rotation, the entire unit, including the cover, is removed from the installation. Outside of the installation, the target rotation is done on a special work rack or the entire unit is replaced.

In the second principle, the drive unit including the media supply is mounted on a side chamber wall. Slewing motions and media are consequently introduced from the side into the process chamber. This may be a freely projecting (cantilevered) construction up to a certain pipe length. An additional support on the other end of the pipe is required for longer pipes. For the target rotation, the target pipe, including the magnetic system found in the interior, is dismounted from the drive unit and lifted from the chamber. Afterwards, the entire target magnetic unit may either be changed or further dismantled and only the actual target pipe replaced.

There are other negative points in the projecting cathodes: there is great force at least on the rear side of the junction point as a result of the design and operation. Furthermore, there must be a precise rotary movement through constant axial orientation, since even smaller deviations in a target length of four meters have enormous negative effects.

Prior art in this regard are mostly simple flange solutions that are connected on the outer diameter using several screws. This may be a mechanically stable connection, but its disadvantage is that all screws need to be individually loosened for disassembly, requiring much space and an enormous amount of time.

Furthermore, different ways for achieving the object are known, in which the connection is made via a combination of union nuts having different geometries on the outer surface of the target.

Another difficulty in creating a connection that should also be mentioned is that there are two different principles of target pipes.

The first principle deals with targets manufactured from a mechanically stable, vacuum-tight and workable thick-walled pipe. In this case, there are no strict limits for the design of the sealing and fastening geometries.

As required by the process, the second principle deals with a thin-walled, but still vacuum-tight and mechanically stable support pipe, on which in turn the actual target material, e.g., Si, Zn, SiAl and all other mechanically unstable materials, are placed in a different way.

One of the tasks was therefore to obtain a connection between the driving gear and the target pipe, which on the one hand is independent of the design of the target pipe, but on the other hand reliably correlates the target magnetic system unit mechanically and using vacuum technology, and furthermore allows a rapid target rotation. At the same time, fast disassembly of the target magnetic system unit should be possible. The target or support pipe should be easy to manufacture at a reasonable price, since this involves an expendable part.

The prior art will be explained in greater detail in the following with the help of some publications.

U.S. Pat. No. 4,356,073 discloses an atomizing and coating device for even substrates having a cylindrical cathode and a magnetic system accommodated parallel to the axis therein. The cathode is open on one side and is provided there with a handle, through which new or other surface parts may be placed section by section by turning the cathode into the range of influence of the race track magnetic field, be it to compensate for the wear or to change the coating material. The magnetic system, the angular position of which can likewise be changed via a lever, is supported via fitted pole pieces—non-slip—on the inner surface of the target pipe. Cooling water is supplied through the tubular magnetic support and flows out of the opening of the target pipe into the open air. The assembly and the replacement of the target pipe, necessitated by wear and tear, is possible only through a circular opening of a correspondingly larger cross section, by unscrewing a straining ring and a bearing ring, in the course of which it may be difficult to thread into its stationary bearing the centric bearing neck, lying opposite, of the target pipe sealed there, without having to open the entire installation.

Through U.S. Pat. No. 4,417,968, a rotation-symmetrical cathode system for magnetron coating of rotating bulk goods in a cylindrical chamber is known, in which a stationary target pipe and a rotatable multipolar magnetic system therein are concentrically arranged. Numerous other magnetron cathodes that are parallel to the axis are arranged with reverse building principle in radial and tangential equidistant distances, i.e., stationary magnetic systems oriented toward the center are arranged within the target pipes rotatable through driving gears. Numerous rod-shaped substrate holders, which are synchronously driven through a planetary gear, are arranged in the more or less ring-shaped space between the central target pipe and the peripheral target pipes. Because of their double-ended orientations, changing all the target pipes requires that the ring-shaped chamber cover having the substrate holders be dismounted, and the assembly and changing the target pipes as well turn out to be difficult and time-consuming because of the depth of the chambers and the need to loosen several screwed connections on the other end of the chamber. Even the cooling systems are to be loosened and opened and then closed again in the process.

Through U.S. Pat. No. 4,422,916, which is a continuation-in-part of U.S. Pat. No. 4,356,073, a continuously working cathode atomizing system for coating even substrates is known starting from FIG. 9. A rotatable target pipe and a magnetic system stored therein in a stationary manner is arranged on the cover of a more or less cuboid-shaped vacuum chamber. Two sleeve shafts of a fixed chamber having the magnetic system are held over pillow blocks with cooling connections. The rotatable target pipe, which is driven via a chain by a concentric toothed wheel, an eccentric pinion gear having a shaft parallel to the axis, and an external electromotor arranged on the chamber, is stored on the said sleeve shafts in a rotatable manner by means of two end walls and bearing bushes arranged therein. Even in this case, an assembly and a change of the target pipe prove to be time-consuming and difficult because for this purpose, the magnetic system also has to be dismantled after taking a chamber cover apart.

Through U.S. Pat. No. 5,437,778 and U.S. Pat. No. 5,529,674, tubular, non-rotatable targets are known, through which the substrates may be led through either axially or through slits through the axis. Furthermore, variations are described, in which ribbon-shaped substrates are led away outside through the slits. Furthermore, planar targets with longitudinal boreholes and slits parallel to the axis are described, through which the ribbon-shaped substrate may be led away. The targets as well as their supporting members are shown as non-rotatable because a turning through radial joining elements for external connections would be prevented. Collet chucks are disclosed for connecting the supporting members and the targets—insofar as symmetrical in rotation—the collet chucks being made of pivoting ring halves having inner conical surfaces and a joint and a straining screw each, whose axis runs perpendicular to the tubular axle. Insofar as magnetic systems are disclosed for the containment of plasma (FIGS. 9 and 20), these are found outside of the target pipe. The invention does not deal with such systems.

Through WO 00/00766, it is known that a radial ring flange is to be arranged at the end of a tubular support shaft for a replaceable tubular target or a target-pipe combination, the radial flange having a step and two lining grooves, onto which the end of the target may be inserted in a water and vacuum tight manner. Here, the ring flange of the support shaft and a further ring flange at the end of the target pipe are connected through a detachable coupling arrangement made up of two semicircular ring halves that may be braced against the ring flange through at least one screw, whose axis is right-angled to the rotational axis.

Here, the ring halves each have at least one conical surface, which is designed to complement one conical surface on the ring flange of the support shaft. Such a coupling arrangement, however, requires considerable free space for positioning tools and for swiveling or removing the ring halves themselves, and considerable tangential sliding movements that consume force and cause wear and tear occur while twisting the ring halves.

Through U.S. Pat. No. 5,098,562, it is known to connect the two ends of a tubular target with two support shafts, each of which exhibits a ring flange on their target side ends. Nothing is said about the type of connection or their detachability. Arranged in the interior of the vacuum chamber for storing the support shafts are pillow blocks—each insulated—of which one is designed to relay current and the other to feed and carry off cooling water. The vacuum and watertight storing requires a complex system of rotary seals, however, the separation of which makes changing the target more difficult.

Through U.S. Pat. No. 5,591,314 and the corresponding WO 97/15697, it is furthermore known to provide the end of a support shaft for a tubular target with a ring flange, whose side turned toward the target exhibits a step having a radial ring surface and a lining groove having a ring seal. The step, however, is only for plane parallel adjusting of support shaft and target and not for centering. Rather, the attempt to center is done through a straining ring and a screw thread connection found on the inside of the straining ring and the outside of the target end. The screw thread connection should preferably occur through two screw-like coiled sections of a steel wire. Even such a coupling arrangement requires considerable room to maneuver to position the tools and to remove the straining ring itself, and considerable tangential sliding movements that consume force and, it should be pointed out in particular, cause wear and tear while twisting the ring halves.

Through U.S. Pat. No. 6,375,815 B1, it is known to provide support shafts of rotatable tubular targets, each having a ring flange and to make the connection with the targets in turn through semi-annular coupling elements, which overlap undercut ring flanges of the targets and rings on the support shafts, and likewise by means of undercut screw thread connections that simultaneously bring about an axial and a radial twisting. Such screw thread connections are made only at great processing cost. Such a coupling arrangement, however, requires considerable room to maneuver to position the tools and to swivel or remove the ring halves themselves, and considerable tangential sliding movements that consume force and cause wear and tear occur while twisting the ring halves.

Although present devices are functional, they are not sufficiently accurate or otherwise satisfactory. Accordingly, a system and method are needed to address the shortfalls of present technology and to provide other new and innovative features.

### SUMMARY OF THE INVENTION

Exemplary embodiments of the present invention that are shown in the drawings are summarized below. These and other embodiments are more fully described in the Detailed Description section. It is to be understood, however, that there is no intention to limit the invention to the forms described in this Summary of the Invention or in the Detailed Description. One skilled in the art can recognize that there are numerous modifications, equivalents and alternative constructions that fall within the spirit and scope of the invention as expressed in the claims.

Embodiment of the present invention relate to a cathode arrangement for atomizing a target pipe (12) having a non-rotatable magnetic system (23) for generating a magnetic field for the containment of a plasma, in which the target pipe (12) is rotatable within a vacuum chamber right through the magnetic field, in which in at least one load bearing structure (1) there is a movable support shaft (6) arranged for the target pipe (12), in which furthermore within the target pipe (12), a fixing device for the magnetic system (23) is arranged, and in which at least one detachable coupling arrangement for changing the target pipe (12) is arranged between the support shaft (6) and the target pipe (12). For the cathode arrangement described at the start, to solve the task of simultaneously bringing about a high and highly loadable coaxiality of support shaft(s) (6) and target pipes (12), a reliable sealing against water and vacuum, and a slight, often repeatable connection and separation—that does not cause much wear and tear—of support shaft(s) (6) and target pipes (12), without the need for much room to maneuver and for much time for the necessary manipulations and to ensure a good concentricity in a constant axial position, it is proposed according to the present invention, to arrange between the movable support shaft (6) and the target pipe (12) a separator (15) coaxial thereto, and two detachable points of separation (32/53), and that through the points of separation (32/53), the torsionally rigid and dimensionally stable connections between the support shaft (6) and the separator (15) on the one hand and the separator (15) and a target pipe (12) on the other hand are detachable and recoverable.

As previously stated, the above-described embodiments and implementations are for illustration purposes only. Numerous other embodiments, implementations, and details of the invention are easily recognized by those of skill in the art from the following descriptions and claims.

### BRIEF DESCRIPTION OF THE DRAWINGS

Various objects and advantages and a more complete understanding of the present invention are apparent and more readily appreciated by reference to the following Detailed Description and to the appended claims when taken in conjunction with the accompanying Drawings wherein:

FIG. 1 illustrates an axial section through a stationary load-bearing structure for a support shaft, a detachable coupling arrangement and the coupling side end of the rotatable target pipe and of the magnetic system accommodated therein;

FIG. 2 illustrates arrangement according to FIG. 1 in a partially uncoupled state;

FIG. 3 illustrates section from the right part of FIG. 2, in an enlarged scale;

FIG. 4 illustrates an axial section through the parts of the driving gear;

FIG. 5 illustrates a radial section along Line V-V in FIG. 3;

FIG. 6 illustrates a perspective representation of a bayonet connection, as they can be used for the connection of a ring flange and a straining ring;

FIG. 7 is a perspective explosive representation of a separated coupling arrangement between a movable support shaft and a target pipe; and

FIG. 8 is a perspective representation of the coupling arrangement according to FIG. 7 in closed or coupled state.

### DETAILED DESCRIPTION

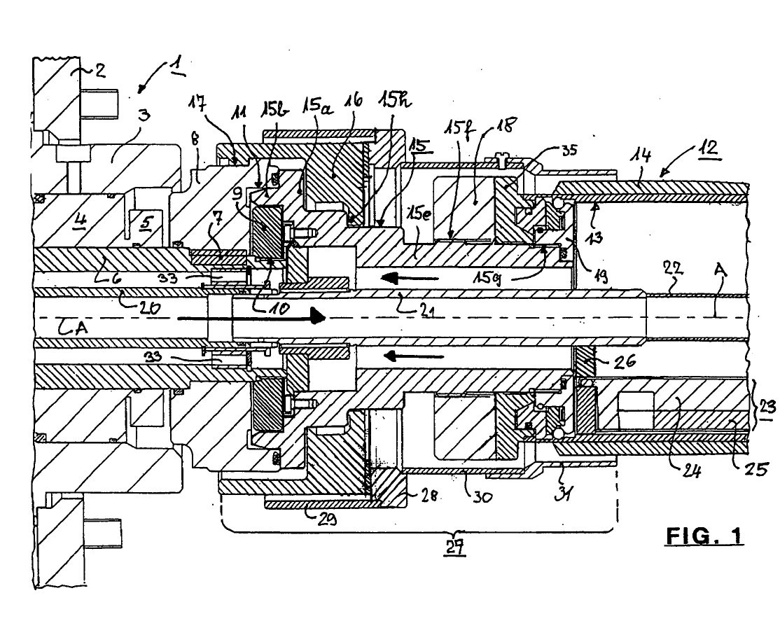

Referring now to the drawings, where like or similar elements are designated with identical reference numerals throughout the several views. Referring first to FIG. 1, it illustrates a load-bearing structure 1, made up of a perpendicular plate 2 and a firmly inserted support pipe 3. A vacuum rotary feed through 4 is tightly sealed here, on whose right end is a radially braceable extension 5. Inserted into this vacuum rotary feed through 4 is a rotatable support shaft 6, on whose right end a ring flange 8 is put on in such a way as to restrict movement via a wedge 7, the ring flange being established in axial direction through a supporting ring 9 via a screw thread connection 10. Between the outer circumference of support ring 9 and ring flange 8 is a coaxial nozzle clearance area parallel to the axis, which forms a first positive-locking element 11.

The system axis A-A, whose spatial position may be chosen, is indicated by a broken line. Load-bearing structure 1 may be fastened in the interior of a vacuum chamber, not shown, on one of the side walls, on the floor or on the ceiling of the vacuum chamber.

Shown on the right of a rotatable target pipe 12, which is made up of a support pipe 13 and a coating 14 out of a coating material, which may be condensed in a non-reactive atmosphere (e.g., argon) on a substrate, not shown, or in a reactive atmosphere as a connection of coating 14. Here, the substrate is moved through a guide parallel to axis A-A and vertical to the plane of projection. These processes are known, however, and will not be described further. For example, support pipe 13 and coating 14 may be made of the same material if this has a sufficient consistency.

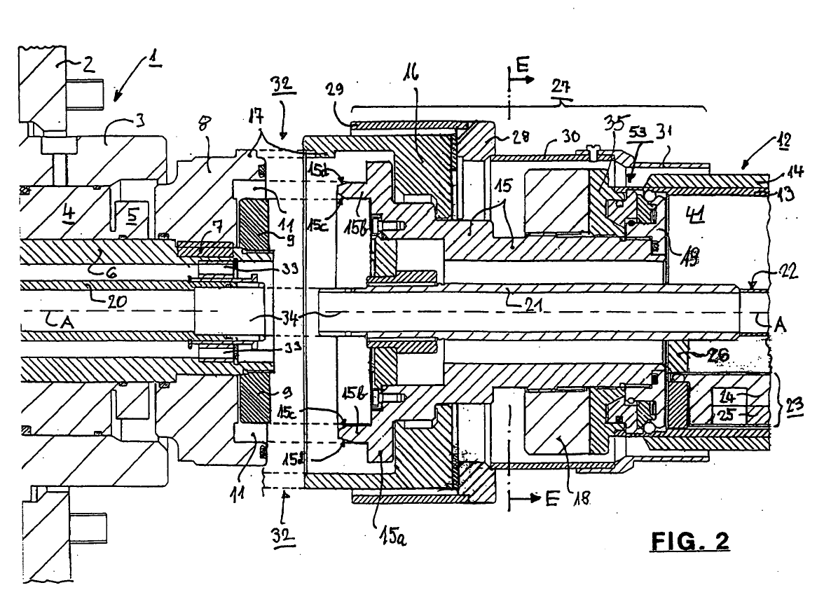

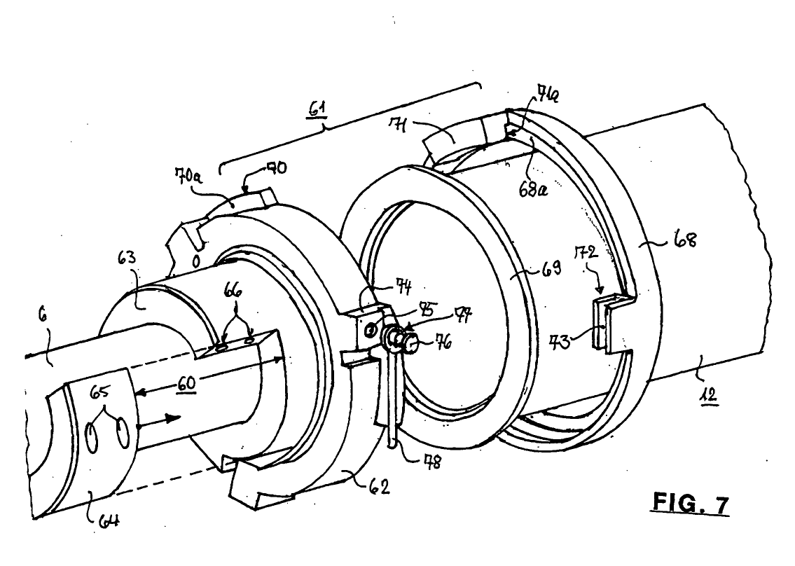

The torque-resistant connection between support shaft 6 and target pipe 12 takes place through the following means: between ring flange 8 and target pipe 12 is a strong bordering separator 15 having a ring flange 15a and a coaxial ring extension 15b, which locks into first positive-locking element 11. For easier threading and for centering, ring extension 15b is provided inside and outside with truncated cone surfaces 15c and 15d (FIG. 2). A first one-piece straining ring 16 having at least one second detachable positive-locking element 17 overlaps ring flange 15a. The connection may be concentrically tightened through bezels, such as a bayonet system (according to FIG. 6) or a thread.

In the further course of separator 15, this has a hollow cylindrical extension 15e having two outer threads 15f and 15g. A second one-piece straining ring 18 and a thrust bearing 19 is screwed onto this extension. Straining ring 16 presses on a ring surface 15h of separator 15.

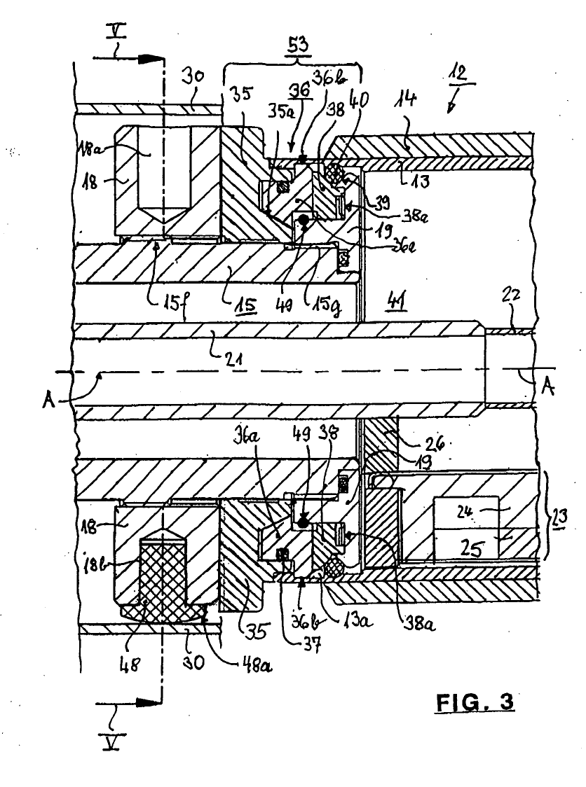

In the interior of support shaft 6, of separator 15 and of target pipe 12 is found—concentrically or parallel to axis A-A—a load-bearing system of pipes 20, 21 and 22, which forms a support for a known, rigid magnetic system 23, made up of yokes 24 and magnets 25. The suspension and determination of position take place through support elements 26, of which only one is shown. The vacuum tight cooling means supply is shown by a thick arrow. Particulars and effects are explained in greater detail with the help of FIG. 3.

FIG. 2 shows the arrangement according to FIG. 1 in partially decoupled state. Almost the entire sector of separator 15 is surrounded by a rotation-symmetrical and coaxial darkroom screen 27, which is made up of a connection ring 26 and hollow cylinders 29, 30 and 31, in which hollow cylinder 31 slightly overlaps the end of target pipe 12.

In FIG. 2, support shaft 6 having ring flange 8 is decoupled on a first point of separation 32, after the straining ring 16 has been loosened from ring flange 8. The end of pipe 20 turned toward first point of separation 32 is coaxially stored in support shaft 6 through a straining ring made of plastic with boreholes 33 for coolant penetration. Ring flange 15a is extracted from positive-locking element 11, likewise pipe 21 from plug-type connector 34 having pipe 20. Darkroom screen 27 may be coaxially pushed toward target pipe 12 and also dismantled so that tools may be put on straining rings 16 and 18. The complex structural component to the right of point of separation 32 may now be removed from the vacuum chamber.

It is emphasized that this complex structural component for relatively short target pipes 12 may be stored in a floating manner, or that for relatively long target pipes 12 an additional storing may be placed on its opposite, right end, which is not shown here, however. The border, in this embodiment, lies between approximately 100 and 200 cm.

FIG. 3 shows an enlarged view of the arrangement according to FIG. 2 to the right of the radial surface plane E-E in FIG. 2—but in a running state. Straining ring 18 has interchanging boreholes 18a and 18b on the circumference. Rod-shaped lathe tools may be inserted into boreholes 18a. Mushroom-shaped support bodies 48 having dome-shaped outer surfaces 48a on which hollow cylinder 30 of darkroom screen 27 is propped up, are put into boreholes 18b.

A second point of separation 53 is found between straining ring 18 and ring-shaped abutment 19 screwed on stay pipe 13 in such a way that it restricts movement and is sealed. Points of separation 32 and 53 are to be considered completely independent of one another. They may be created within the scope of claim 1 completely independent of one another and, within the scope of the exemplary embodiment, do not have any compelling combinatorial character.

FIG. 3 shows within point of separation 53 an axially movable thrust collar 35, which has a concentric truncated cone surface 35a. An expander 36 is arranged thereon, sector-pattern sleeves 36a having outer surfaces 36b, which by twisting straining ring 18 are retractable in radial directions into an inner ring-shaped recess 13a of stay pipe 13 in order to lay down stay pipe 13 in axial and radial direction. In the course of screwing back straining ring 18, sleeves 36a are radially drawn together through annular spring 37 to release target pipe 12.

Arranged between sleeves 36 and thrust bearing 19 is a further thrust collar 38, which together with thrust bearing 19 includes V-shaped snap ring groove 39 that opens outwards, in which there is an elastomer sealing ring 40. In the course of twisting the device, sealing ring 40 is pressed against a cylindrical inner surface of stay pipe 19 in order to seal coolant-filled space 41 within stay pipe 13 and target pipe 12 against the vacuum in the vacuum chamber.

For purposes of compensating the assembly state according to FIG. 3, straining ring 18 is screwed back to the left. As a result, thrust collar 35 becomes axially freely movable. Annular spring 37 tightens, as a result of which sleeves 36a slide on truncated cone surface 35a and its outer surfaces 36b release stay pipe 13 with coating 14 from atomizing material. Thrust collar 38 follows the movement under the influence of a wave-shaped annular spring 38a until a limiting ring 49 made up of a spring steel wire open on one side, as a result of which snap ring groove 39 widens and sealing ring 40 can tighten and likewise loosen from stay pipe 13. Target pipe 12 may now be pulled off in axial direction toward the right. The restoration of the operating state according to FIGS. 1 and 3 follows in the reverse.

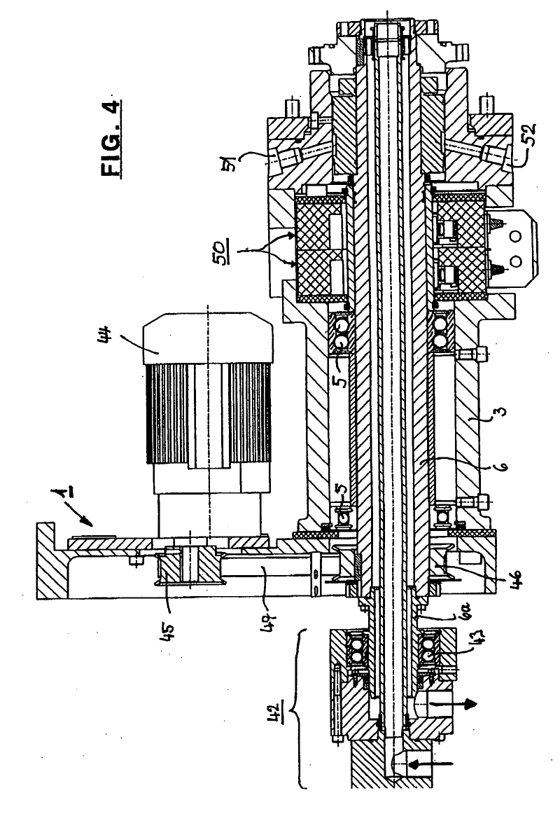

Load-bearing structure 1 is shown freely in space in FIG. 4—while continuing the reference figures. Support shaft 6 is rotatably stored over roller bearing 5 in stay pipe 3. Support shaft 6 has extension 6a, on which via roller bearing 43 a rotation coupling 42 is stored in a stationary manner for coolant supply and carrying off.

Such types of rotation couplings 42 for liquids are known in themselves, however, so that a description of other particulars may be dispensed with. The actuation of support shaft 6 takes place via motor 44, two pulleys 45 and 46, and a transmission belt 47. Sliding contacts 50 are provided for the supply of atomizing voltage. Connecting channels 51 and 52 are provided for the supply and carrying off of coolants.

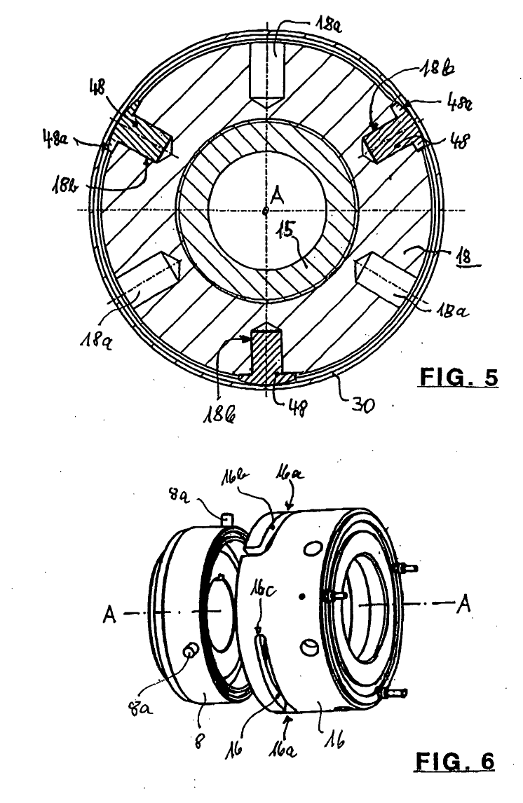

FIG. 5 shows a radial section along line V-V in FIG. 3. Arranged on the circumference of straining ring 18, at equidistant distribution and radial directions, are boreholes 18a for inserting a rod-shaped tool and 18b for putting in support bodies 48, which are mushroom-shaped and provided with dome-shaped outer surfaces 48a, on which darkroom screen 27 that turns along with it is propped up.

FIG. 6 shows a perspective representation of a bayonet connection, as it may be used for connecting a ring flange 8 and straining ring 16. Ring flange 8 is fastened in a twist-proof manner at the end of support shaft 6; three pin rockers 8a are arranged on its circumference at equidistant distribution. Found in analogous arrangement in straining ring 16 are three L-shaped columns 16a having intakes and flanks 16b parallel to the axis, which run in a selectively ascending manner to the right toward their ends 16c in axial direction, so that the bayonet connection tightens and loosens again sensitively and without much effort while putting together and twisting. The threaded joint may be made non-detachable without tools using lock screws, not shown here.

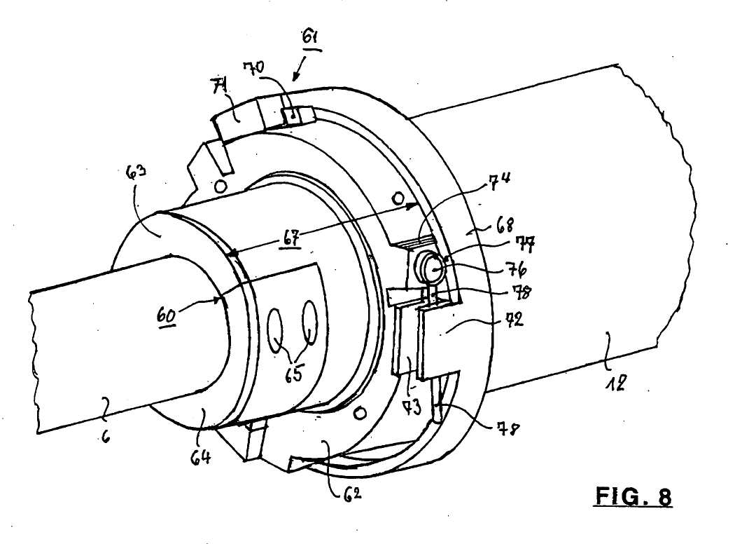

Shown on the left of FIG. 7 is the chamber inner end of such a support shaft 6, on which a first point of separation 60 is arranged on the left and on the right, beside it, a second point of separation 61. The first point of separation 60 is formed through a ring flange 62 having a hub 63, which is halved on a portion of its length, and at this point, is supplemented by a semi-ring-shaped thrust piece 64, which is shown only partially here. The connection takes place by pushing in the direction of the arrow and by twisting by means of screws and screw holes 65 and 66. This twisting, which—symmetrical in rotation—is then torque- and flex-resistant, forms a separator 67 together with ring flange 62 (FIG. 8).

The second point of separation 61 is made up of two combinable parts that are positive-locking with one another, namely ring flange 62 and straining ring 68. The connection initially takes place by pushing a target pipe 12 to the left, which at least on one end has a ring flange 69 that sticks out radially outwards. Target pipe 12 may be monolithically constructed for mechanically highly stable atomizing materials, but in less durable non-metallic materials, may also made of a metallic inner pipe and an outer coating made of atomizing materials, such as for example, Si, Zn, SiAl, etc.

The fixing of ring flange 69, and consequently, of target pipe 12, follows in a positive-locking and non-positive manner through straining ring 68, which is part of a bayonet connection and through which ring flange 69 and ring flange 62 is non-rigid to the left and is also twistable compared with ring flange 62. To produce the positive-locking, ring flange 62 has on its outer circumference at least one latch 70, which after the twisting of straining ring 68 is each overlapped by a hook ring sector 71. Flanks 70a of latch(es) 70 that overlap in the process and inner surface(s) 71a of ring sectors 71 may include in the process in axial direction an angle of pressure with a slight slope (as for a screw thread). Straining ring 68 has a step-by-step indentation 68a.

To fix the twisting angle, straining ring 68 has a fork part 72 having a tangential slit 73. On the other hand, ring flange 62 has a radial overhang 74 having a screw hole 75, into which a draw spindle 76 is screwed in. Between overhang 74 and the head of draw spindle 78 is a ring 77, from which a retention pin 78 sticks out radially to the screw axis but tangentially to ring flange 62, the retention pin engaging in a pushed together state, in accordance with FIG. 8, into slit 73.

FIG. 8 shows a perspective representation of the coupling arrangement according to FIG. 7 in closed or coupled state. It can be seen that hub 63 and thrust piece 64 screws down almost together and with support shaft 6, completing a rotational solid, which together with ring flange 6 forms a unit, which is indeed detachable.

Ring flange 69 of target pipe 12 is arranged between ring flange 62 and straining ring 68. However, it is now visible that latch 70 juts slightly behind ring sector 71 and in this manner forms a positive-locking connection.

This also applies to any other connections of this type. Ring flange 69 of target pipe 12 lies in recess 68a of straining ring 68. Straining screw 76 is tightened, and retention pin 78 now lies within slit 73.

In the interior of rotatable target pipe 12 is found—as in FIGS. 1 to 4 as well—a non-rotating magnetic system, not shown here, under whose lines of electric flux target pipe 12 runs through in operation. Supports and lines for the magnetic system and its coolant run through support shaft 6 until target pipe 12, but are likewise not shown here.

In conclusion, the present invention provides, among other things, a system and method for arranging a cathode and/or and associated target pipe. Those skilled in the art can readily recognize that numerous variations and substitutions may be made in the invention, its use and its configuration to achieve substantially the same results as achieved by the embodiments described herein. Accordingly, there is no intention to limit the invention to the disclosed exemplary forms. Many variations, modifications and alternative constructions fall within the scope and spirit of the disclosed invention as expressed in the claims.

What is claimed is:

1. A quick attachment system for cathodes, the system comprising:
a laterally movable support shaft;
a flange connected to the support shaft, the flange including a cavity locking element and a shoulder locking element;
a bordering separator connectable to a target pipe, the bordering separator comprising ring extensions for engaging the cavity locking element of flange; and
a straining ring configured to engage the bordering separator and the shoulder locking element of the flange to thereby secure the laterally movable shaft to the target pipe.

2. The system of claim 1, wherein the straining ring is a one-piece straining ring.

3. The system of claim 1, wherein the bordering separator is configured to rotate coaxially when engaged with the cavity locking element of the flange.

4. The system of claim 1, further comprising:
a support structure configured to support the support shaft.

5. A rotatable cathode system comprising:
a target pipe;
a laterally movable, rotatable support shaft configured to rotate the target pipe;
a flange connected to the support shaft, the flange including a cavity locking element and a shoulder locking element;
a bordering separator connectable to a target pipe, the bordering separator comprising ring extensions for engaging the cavity locking element of flange; and
a straining ring configured to engage the bordering separator and the shoulder locking element of the flange to thereby secure the laterally movable shaft to the target pipe.

6. A rotatable cathode system comprising:
a target pipe including a target-pipe ring flange;
a rotatable support shaft configured to rotate the target pipe;
a support-shaft ring flange connected to the support shaft, the support-shaft ring flange including a latch; and
a straining ring configured to engage the support-shaft ring flange and the latch to thereby secure the support shaft to the target pipe.

7. The system of claim 6, further comprising:
a thrust piece engagable with the target pipe; and
a hub engagable with the thrust piece and the target-pipe flange.

8. The system of claim 6, wherein the straining ring comprises a fork connector.

9. The system of claim 8, wherein the support-shaft ring flange comprises a retention pin for engaging the fork connector.

10. A target pipe system for securing a target pipe to a rotatable support shaft that includes a support-shaft ring flange, the system comprising:
a target pipe including a target-pipe ring flange; and
a straining ring configured to engage the target-pipe flange and the support-shaft ring flange to thereby secure the support shaft to the target pipe.

11. The system of claim 10, wherein the straining ring includes a hook ring sector for engaging a latch on the support-shaft ring flange.

12. A target pipe system for securing a target pipe to a support shaft that includes a flange with a cavity locking element and a shoulder element, the system comprising:
a bordering separator connectable to a target pipe, the bordering separator comprising ring extensions for engaging the cavity locking element of flange; and
a straining ring configured to engage the bordering separator and the shoulder locking element of the flange to thereby secure the laterally movable shaft to the target pipe.
